(19) United States
(12) Patent Application Publication
(10) Pub. No.: US 2025/0007240 A1
(43) Pub. Date: Jan. 2, 2025

(54) DML DRIVER

(71) Applicants: Nippon Telegraph and Telephone Corporation, Tokyo (JP); NTT Innovative Devices Corporation, Yokohama-shi (JP)

(72) Inventors: Toshiki Kishi, Tokyo (JP); Tadashi Minotani, Tokyo (JP); Nobuhiro Toyoda, Yokohama-shi (JP); Yoshikazu Urabe, Yokohama-shi (JP)

(21) Appl. No.: 18/688,644

(22) PCT Filed: Sep. 3, 2021
(86) PCT No.: PCT/JP2021/032398

§ 371 Date: Sep. 19, 2024

(51) Int. Cl. H01S 5/062

(52) U.S. Cl. CPC H01S 5/06213

(57) ABSTRACT

A DML driver (10) includes a PMOS transistor (M₁ₚ) having a gate connected to a bias voltage (V₂), a source connected to a power supply voltage (V₁), and a drain connected to the anode of an LD (1), an NMOS transistor (M₁ₙ) having a source connected to ground, an inductor (L₁) having one end to which a modulated signal (Vᵢₙ) is input, and the other end connected to the gate of the NMOS transistor (M₁ₙ), and a resistor (Rᵢₙ) having one end connected to a bias voltage (V₄), and the other end connected to one end of the inductor (L₁).

### TECHNICAL FIELD

The present invention relates to a technique of driving a directly modulated laser (DML) and, more particularly, to a DML driver having a peaking function and a shaping function to a light waveform.

### BACKGROUND ART

These days, the traffic amount of communication is increasing year by year around the world along with a remarkable spread of SNS (Social Networking Service). A further increase in traffic amount is expected in the future because of the development of IoT (Internet of Things) and cloud computing technologies. To cope with an enormous traffic amount, large communication capacities inside and outside data centers are required.

As the capacity increases, standardization of 100 GbE is complete at present in the Ethernet® standard, which is a main standard component of a network, and standardization of 400 GbE aiming at larger capacities is being discussed. For application to 400 GbE, a driver using DML is drawing attention in terms of low power consumption (see Non-Patent Literature 1).

FIG. 10 is a circuit diagram showing the arrangement of a conventional DML driver. The DML driver includes a PMOS transistor M₁ₚ having a gate connected to a bias voltage V₂, a source connected to a power supply voltage V₁, and a drain connected to the anode of a laser diode (LD) 1, an NMOS transistor M₁ₙ having a gate to which a modulated signal Vᵢₙ is input, and a source connected to ground, an NMOS transistor M₂ₙ having a gate connected to a bias voltage V₃, a drain connected to the drain of the PMOS transistor M₁ₚ and the anode of the LD 1, and a source connected to the drain of the NMOS transistor M₁ₙ, and a resistor Rᵢₙ having one end connected to a bias voltage V₄, and the other end connected to the gate of the NMOS transistor M₁ₙ.

The NMOS transistors M₁ₙ and M₂ₙ are cascode-connected. The cascode connection improves the frequency characteristic compared to the single NMOS transistor M₁ₙ. Even when the operating voltage of the LD 1 exceeds the breakdown voltage of the single NMOS transistor, it is divided by the cascode connection and the voltage breakdown of the NMOS transistors M₁ₙ and M₂ₙ can be prevented. The resistor Rᵢₙ is an impedance matching resistor.

As shown in FIG. 10, in the arrangement of the conventional driver circuit, the driver portion does not have a function of compensating for the band of the LD. Thus, the band of a transmission front end constituted by the DML driver and the LD is undesirably rate-determined by the band of the LD.

### RELATED ART LITERATURE

### Non-Patent Literature

Non-Patent Literature 1: T. Kishi et al., “A 137-mw, 4 ch×25-Gbps low-power compact transmitter flip-chip-bonded 1.3-μm LD-array-on-Si”, In Proceedings of the Optical Fiber Communication Conference and Exhibition, 2018, Paper M2D.2.

### DISCLOSURE OF INVENTION

### Problem to be Solved by the Invention

The present invention has been made to solve the above-described problems, and has as its object to provide a DML driver capable of compensating for the band of an LD.

### Means of Solution to the Problem

A DML driver according to the present invention comprises a first transistor having a gate or base connected to a first bias voltage, a source or emitter connected to a first power supply voltage, and a drain or collector connected to an anode of a laser diode; a second transistor having a drain or collector connected to the anode of the laser diode, and a source or emitter connected to a second power supply voltage; an inductor having one end to which a modulated signal is input, and the other end connected to a gate or base of the second transistor; and a first resistor having one end connected to a second bias voltage, and the other end connected to the one end of the inductor.

An arrangement example of the DML driver according to the present invention further comprises a third transistor having a gate or base connected to a third bias voltage, and cascode-connected between the anode of the laser diode and the drain or collector of the second transistor.

A DML driver according to the present invention comprises a first transistor having a gate or base connected to a first bias voltage, a source or emitter connected to a first power supply voltage, and a drain or collector connected to an anode of a laser diode; a second transistor having a gate or base connected to a second bias voltage, and a source or emitter connected to a second power supply voltage; a third transistor cascode-connected between the anode of the laser diode and a drain or collector of the second transistor; an inductor having one end to which a modulated signal is input, and the other end connected to a gate or base of the third transistor; and a first resistor having one end connected to a third bias voltage, and the other end connected to the one end of the inductor.

An arrangement example of the DML driver according to the present invention further comprises a first capacitor having one end connected to the first power supply voltage; and a second resistor having one end connected to the other end of the first capacitor, and the other end connected to the drain or collector of the first transistor.

An arrangement example of the DML driver according to the present invention further comprises a fourth transistor having a gate or base connected to a fourth bias voltage, and cascode-connected between the drain or collector of the first transistor and the anode of the laser diode.

An arrangement example of the DML driver according to the present invention further comprises a third resistor inserted between the source or emitter of the second transistor and the second power supply voltage.

An arrangement example of the DML driver according to the present invention further comprises a second capacitor parallel-connected to the third resistor.

### Effect of the Invention

According to the present invention, the band of an LD can be compensated for by the frequency peaking effect of an inductor.

### BRIEF DESCRIPTION OF DRAWINGS

FIG. 1 is a circuit diagram showing the arrangement of a DML driver according to the first embodiment of the present invention;

FIG. 2 is circuit diagram showing the resistive component and the capacitive component between the gate and source of the NMOS transistor of the DML driver according to the first embodiment of the present invention;

FIG. 3 is a graph showing results of simulating the EO response characteristic of the DML driver and LD for a conventional arrangement and the first embodiment of the present invention;

FIGS. 4A to 4C are charts showing results of simulating the optical output waveform of the LD for the conventional arrangement and the embodiment;

FIG. 5 is a circuit diagram showing the arrangement of a DML driver according to the second embodiment of the present invention;

FIG. 6 is a circuit diagram showing the arrangement of a DML driver according to the third embodiment of the present invention;

FIG. 7 is a circuit diagram showing the arrangement of a DML driver according to the fourth embodiment of the present invention;

FIG. 8 is a circuit diagram showing the arrangement of a DML driver according to the fifth embodiment of the present invention;

FIG. 9 is a circuit diagram showing the arrangement of a DML driver according to the sixth embodiment of the present invention; and

FIG. 10 is a circuit diagram showing the arrangement of a conventional DML driver.

### BEST MODE FOR CARRYING OUT THE INVENTION

### Principle of Invention

According to the present invention, an inductor is series-connected to the gate of a transistor (M₁ₙ) to which a modulated signal Vᵢₙ is input, so a frequency peaking function can operate to compensate for the band of an LD. Further, a series-connected element of a capacitor and resistor is connected parallel to a transistor (M₁ₚ) that supplies a current to the LD, and the overshoot and undershoot of a light waveform can be suppressed to shape the light waveform.

### First Embodiment

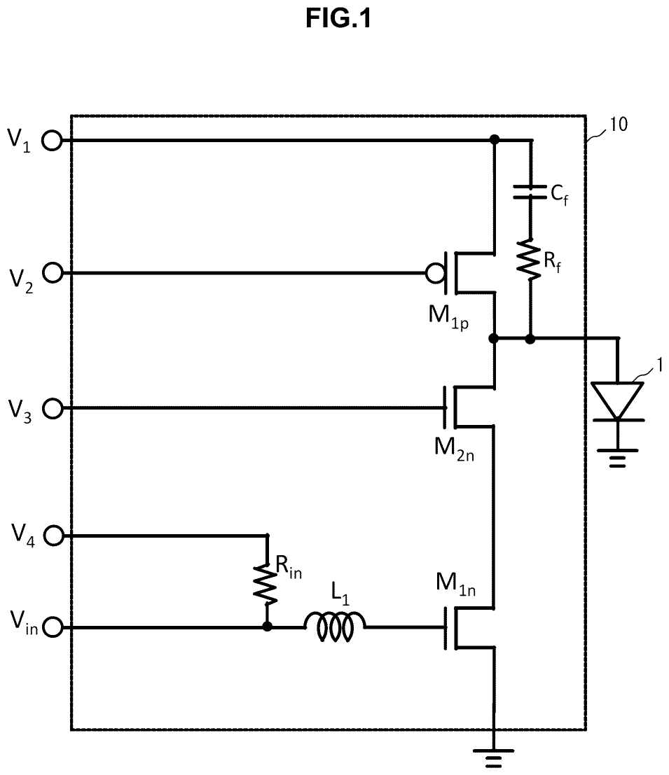

Embodiments of the present invention will be described below with reference to the accompanying drawings. FIG. 1 is a circuit diagram showing the arrangement of a DML driver according to the first embodiment of the present invention. A DML driver 10 according to the embodiment includes a PMOS transistor M₁ₚ having a gate connected to a bias voltage V₂ (first bias voltage), a source connected to a power supply voltage V₁ (first power supply voltage), and a drain connected to the anode of an LD 1, an NMOS transistor M₁ₙ having a source connected to ground (second power supply voltage), an NMOS transistor M₂ₙ having a gate connected to a bias voltage V₃ (third bias voltage), a drain connected to the drain of the PMOS transistor M₁ₚ and the anode of the LD 1, and a source connected to the drain of the NMOS transistor M₁ₙ, an inductor L₁ having one end to which a modulated signal Vᵢₙ is input, and the other end connected to the gate of the NMOS transistor M₁ₙ, a resistor Rᵢₙ having one end connected to a bias voltage VA (second bias voltage), and the other end connected to one end of the inductor L₁, a capacitor C_{f} having one end connected to the power supply voltage V₁, and a resistor R_{f} having one end connected to the other end of the capacitor C_{f}, and the other end connected to the drain of the PMOS transistor M₁ₚ and the anode of the LD 1.

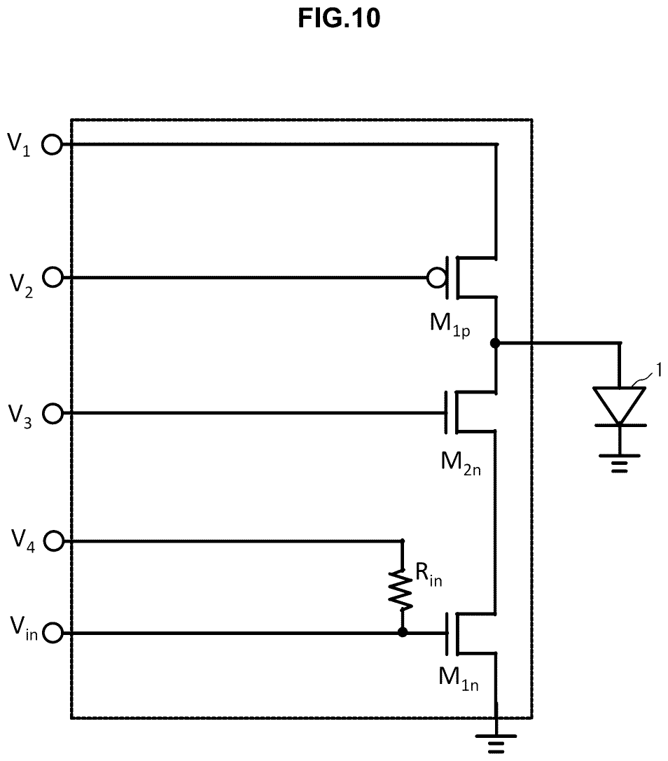

These voltages have a magnitude relationship: V₁>V₂>V₃>V₄>GND (ground). In the embodiment, unlike the circuit arrangement of FIG. 10, the inductor L₁ is interposed between the modulated signal Vᵢₙ and the gate of the NMOS transistor M₁ₙ, and the series-connected element of the capacitor C_{f} and resistor R_{f} is connected parallel to the PMOS transistor M₁ₚ.

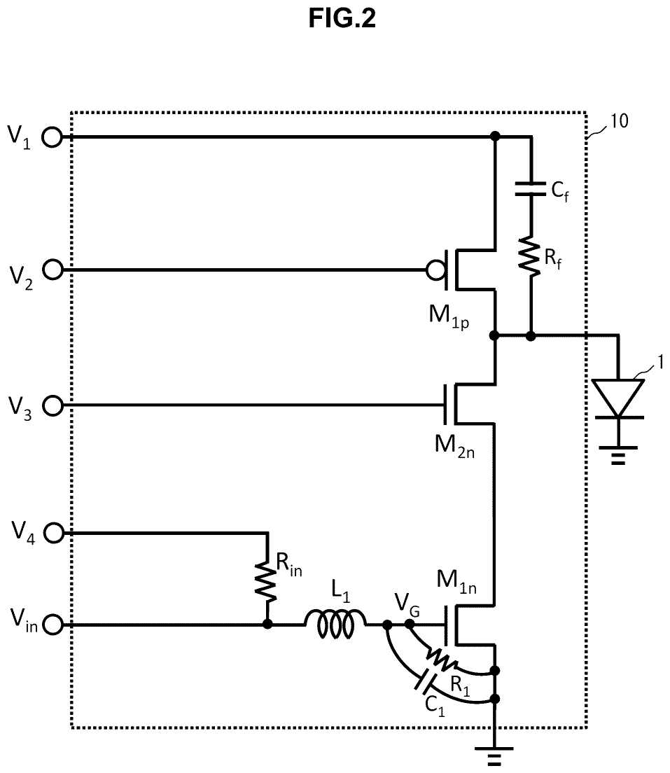

FIG. 2 shows the circuit arrangement of the embodiment including the resistive component and the capacitive component between the gate and source of the NMOS transistor M₁ₙ. Letting R₁ be the resistance between the gate and source of the NMOS transistor M₁ₙ, C₁ be the capacitance between the gate and the source, and V_{G} be the gate voltage, |V_{G}/Vᵢₙ| can be given by equation (1):

$$\vert \frac{{V}_{G}}{{V}_{in}} ( ω ) \vert = \frac{1}{{( 1 - {ω}^{2} {C}_{1} {L}_{1} )}^{2} + \frac{{ω}^{2} {L}_{1}^{2}}{{R}_{1}^{2}}} \sqrt{{( 1 - {ω}^{2} {C}_{1} {L}_{1} )}^{2} + \frac{{ω}^{2} {L}_{1}^{2}}{{R}_{1}^{2}}} \qquad ( 1 )$$

where ω is the angular frequency. If |V_{G}/Vᵢₙ|>1 is satisfied for 1−ω²C₁L₁=0, the frequency peaking effect is obtained. It is therefore necessary to set the inductance value of L₁ so as to satisfy relation (2):

$$\sqrt{\frac{{L}_{1}}{{C}_{1}}} < {R}_{1} \qquad ( 2 )$$

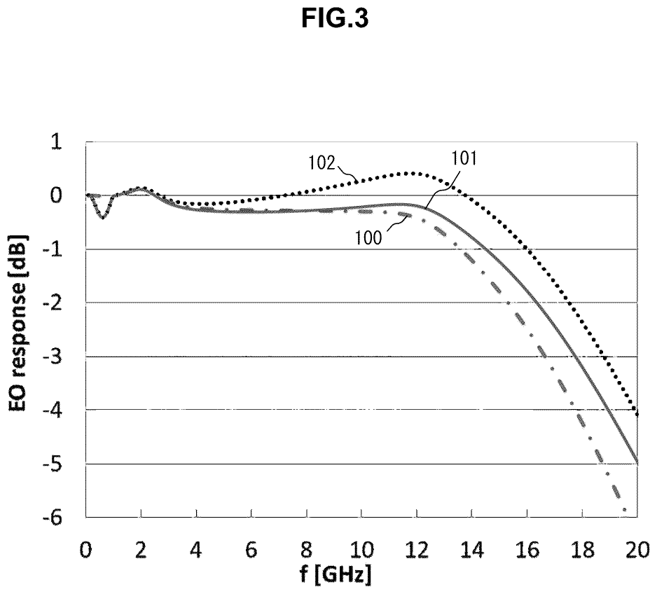

FIG. 3 shows results of simulating the EO (Electrical-to-Optical) response characteristic of the DML driver and LD 1 for the conventional arrangement and the embodiment. In FIG. 3, reference numeral 100 denotes an EO response characteristic in the conventional arrangement shown in FIG. 10; 101, an EO response characteristic in the embodiment; and 102, an EO response characteristic in a state in which the capacitor C_{f} and the resistor R_{f} are removed from the arrangement of the embodiment. As is apparent from FIG. 3, the result of the circuit arrangement to which the inductor L₁ is added exhibits an increase in the band of the EO response characteristic in comparison with the conventional circuit arrangement.

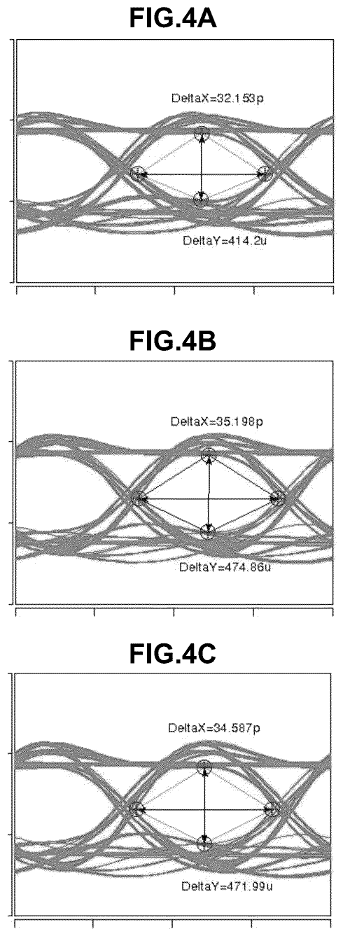

FIGS. 4A to 4C show results of simulating the optical output waveform of the LD 1 for the conventional arrangement and the embodiment. The scale of the amplitude along the ordinate is 500 μW/div, and that of the time along the abscissa is 20 ps/div. FIG. 4A shows an optical output waveform when the conventional arrangement is used, FIG. 4B shows an optical output waveform when the arrangement of the embodiment is used, and FIG. 4C shows an optical output waveform in the state in which the capacitor C_{f} and the resistor R_{f} are removed from the arrangement of the embodiment.

A comparison between FIGS. 4A, 4B, and 4C reveals that in the embodiment, the eye opening is improved in both the abscissa (time) direction and the ordinate (amplitude) direction by adding the inductor L₁. A comparison between FIGS. 4B and 4C represents that in the embodiment, the overshoot and undershoot of the optical output waveform are suppressed by adding the capacitor C_{f} and the resistor R_{f}, and the eye opening is improved in both the abscissa direction and the ordinate direction.

As represented by the EO response characteristic in FIG. 3, when the capacitor C_{f} and the resistor R_{f} are removed from the arrangement of the embodiment, frequency peaking acts excessively strongly, the band is widened compared to a case in which the capacitor C_{f} and the resistor R_{f} are added, but the group delay characteristic of the DML driver and LD 1 deteriorates. From the results in FIGS. 3, 4B, and 4C, the overshoot and undershoot of the optical output waveform can be suppressed by adding the capacitor C_{f} and the resistor R_{f}.

As described above, according to the embodiment, the band of the LD 1 can be compensated for by the frequency peaking effect of the inductor L₁. Also, according to the embodiment, the overshoot and undershoot of the optical output waveform of the LD 1 can be suppressed to shape the optical output waveform by the series-connected element of the capacitor C_{f} and resistor R_{f}.

### Second Embodiment

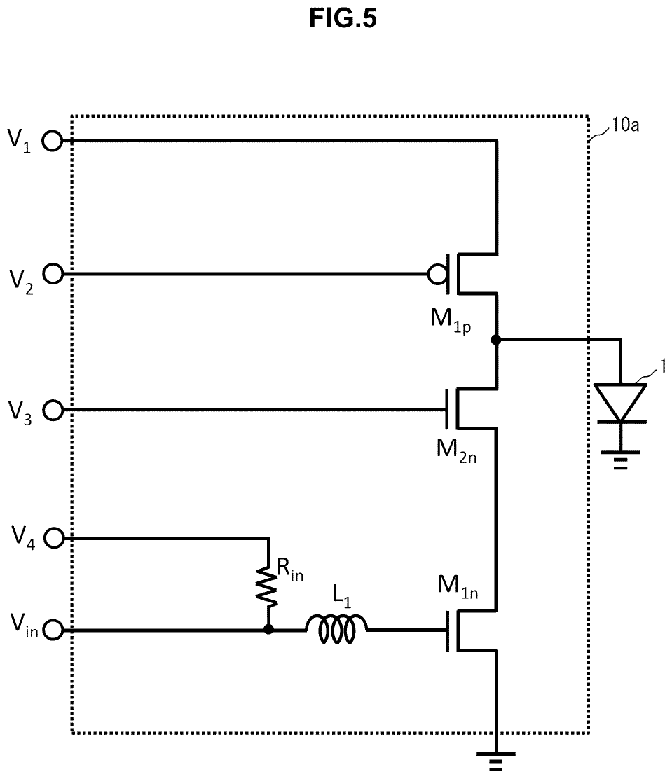

Next, the second embodiment of the present invention will be described. FIG. 5 is a circuit diagram showing the arrangement of a DML driver according to the second embodiment of the present invention. A DML driver 10a according to the embodiment is constituted by removing the capacitor C_{f} and the resistor R_{f} from the DML driver 10 according to the first embodiment.

Some commercially available LDs vary in characteristics and have narrow bands. When an LD of a narrow band is used as an LD 1, a circuit arrangement in which the capacitor C_{f} and the resistor R_{f} are removed from the first embodiment so that frequency peaking acts strongly can compensate for the band of the LD 1 without deteriorating the group delay characteristic. Hence, the embodiment in which the capacitor C_{f} and the resistor R_{f} are removed from the first embodiment can be an effective circuit arrangement when the band of the LD 1 is narrow.

### Third Embodiment

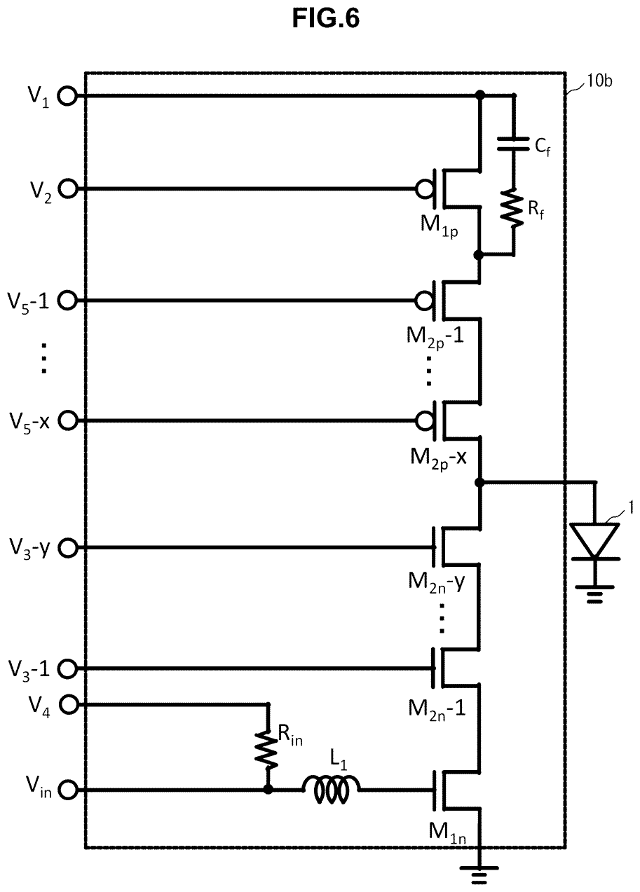

Next, the third embodiment of the present invention will be described. FIG. 6 is a circuit diagram showing the arrangement of a DML driver according to the third embodiment of the present invention. A DML driver 10b according to the embodiment includes a PMOS transistor M₁ₚ, an NMOS transistor M₁ₙ, one or more PMOS transistors M₂ₚ-1 to M₂ₚ-x having gates connected to bias voltages V₅-1 to V₅-x (fourth bias voltages) and cascode-connected between the drain of the PMOS transistor M₁ₚ and the anode of an LD 1, one or more NMOS transistors M₂ₙ-1 to M₂ₙ-y having gates connected to bias voltages V₃-1 to V₃-y (third bias voltages) and cascode-connected between the anode of the LD 1 and the drain of the NMOS transistor M₁ₙ, an inductor L₁, a resistor Rᵢₙ, a capacitor C_{f}, and a resistor R_{f}.

These voltages have a magnitude relationship: V₁>V₂>V₅-1> . . . >V₅-x>V₃-y> . . . >V₃-1>V₄>GND (ground). The cascode connection of the PMOS transistor may be implemented by connecting its source to the drain of a PMOS transistor at an upper stage, and its drain to the source of a PMOS transistor at a lower stage or the anode of the LD 1. The cascode connection of the NMOS transistor may be implemented by connecting its source to the drain of an NMOS transistor at a lower stage, and its drain to the source of an NMOS transistor at an upper stage or the anode of the LD 1.

In this manner, a multistage circuit arrangement can be adopted to prevent the voltage breakdown of both the PMOS and NMOS transistors. This is effective for a front-end node because the breakdown voltage per single transistor decreases. Here, the PMOS transistors M₂ₚ-1 to M₂ₚ-x cascode-connected to the PMOS transistor M₁ₚ are arranged at x stages, and the NMOS transistors M₂ₙ-1 to M₂ₙ-y cascode-connected to the NMOS transistor M₁ₙ are arranged at y stages. Both x and y are one or more.

### Fourth Embodiment

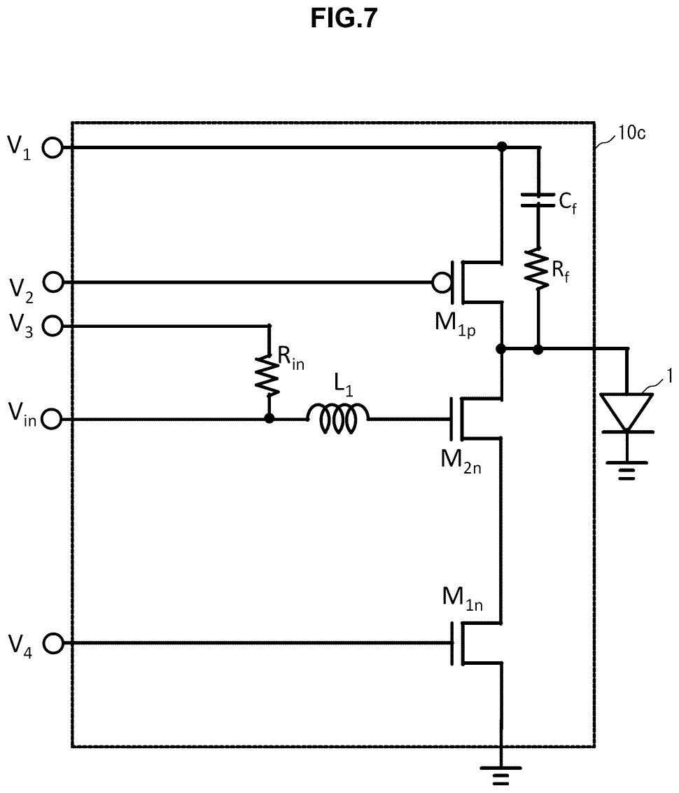

Next, the fourth embodiment of the present invention will be described. FIG. 7 is a circuit diagram showing the arrangement of a DML driver according to the fourth embodiment of the present invention. A DML driver 10c according to the embodiment includes a PMOS transistor M₁ₚ having a gate connected to a bias voltage V₂, a source connected to a power supply voltage V₁, and a drain connected to the anode of an LD 1, an NMOS transistor M₁ₙ having a gate connected to a bias voltage V₄, and a source connected to ground, an NMOS transistor M₂ₙ having a drain connected to the drain of the PMOS transistor M₁ₚ and the anode of the LD 1, and a source connected to the drain of the NMOS transistor M₁ₙ, an inductor L₁ having one end to which a modulated signal Vᵢₙ is input, and the other end connected to the gate of the NMOS transistor M₂ₙ, a resistor Rᵢₙ having one end connected to a bias voltage V₃, and the other end connected to one end of the inductor L₁, a capacitor C_{f}, and a resistor R_{f}.

In the first embodiment, the modulated signal Vᵢₙ is input to the gate of the NMOS transistor M₁ₙ via the inductor L₁. In the fourth embodiment, the modulated signal Vᵢₙ is input to the gate of the NMOS transistor M₂ₙ via the inductor L₁. According to the fourth embodiment, a current flowing from the PMOS transistor M₁ₚ to the NMOS transistors M₂ₙ and M₁ₙ can be adjusted by adjusting the bias voltage V₄ applied to the gate of the NMOS transistor M₁ₙ.

In the fourth embodiment, the NMOS transistor M₂ₙ cascode-connected to the NMOS transistor M₁ₙ is arranged at one stage (y=1), but a plurality of NMOS transistors M₂ₙ-1 to M₂ₙ-y may be connected (y≥2), as described in the third embodiment. In this case, the inductor L₁ can be connected between the modulated signal Vᵢₙ and the gate of one NMOS transistor M₂ₙ-k (k is one of 1 to y) out of the NMOS transistors M₂ₙ-1 to M₂ₙ-y, and the resistor Rᵢₙ can be connected between the inductor L₁ and the bias voltage V₃-k that is applied to the NMOS transistor M₂ₙ-k.

In the embodiment, letting R₁ be the resistance between the gate and source of the NMOS transistor M₂ₙ or M₂ₙ-k to which the inductor L₁ is connected, and C₁ be the capacitance between the gate and the source, it is necessary to set the inductance value of L₁ so as to satisfy relation (2), as described above.

### Fifth Embodiment

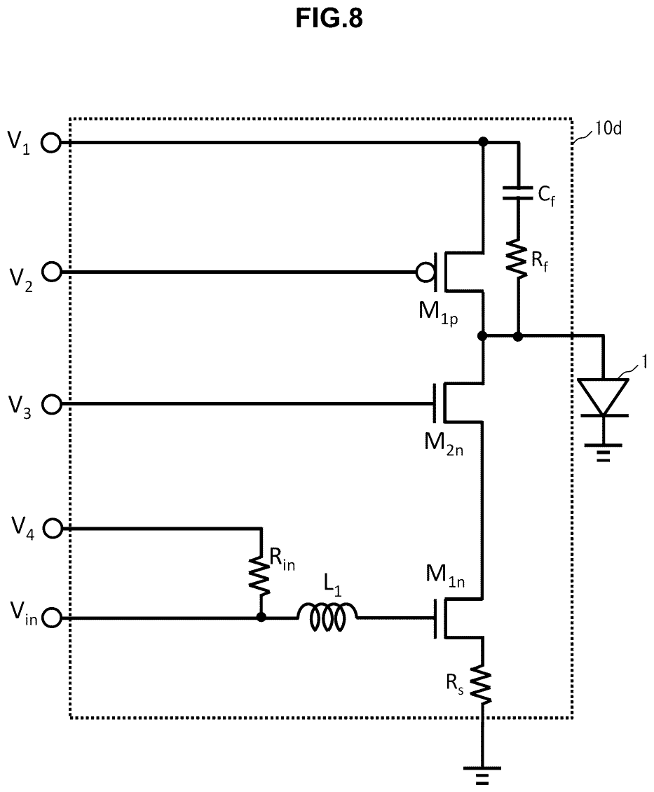

Next, the fifth embodiment of the present invention will be described. FIG. 8 is a circuit diagram showing the arrangement of a DML driver according to the fifth embodiment of the present invention. A DML driver 10d according to the fifth embodiment is constituted by inserting a resistor Rₛ between the source of an NMOS transistor M₁ₙ and ground in the DML driver 10 according to the first embodiment. In the fifth embodiment, the DML driver can be operated more linearly with respect to a modulated signal Vᵢₙ.

Although the resistor Rₛ is applied to the first embodiment in FIG. 8, it may be applied to the second to fourth embodiments.

### Sixth Embodiment

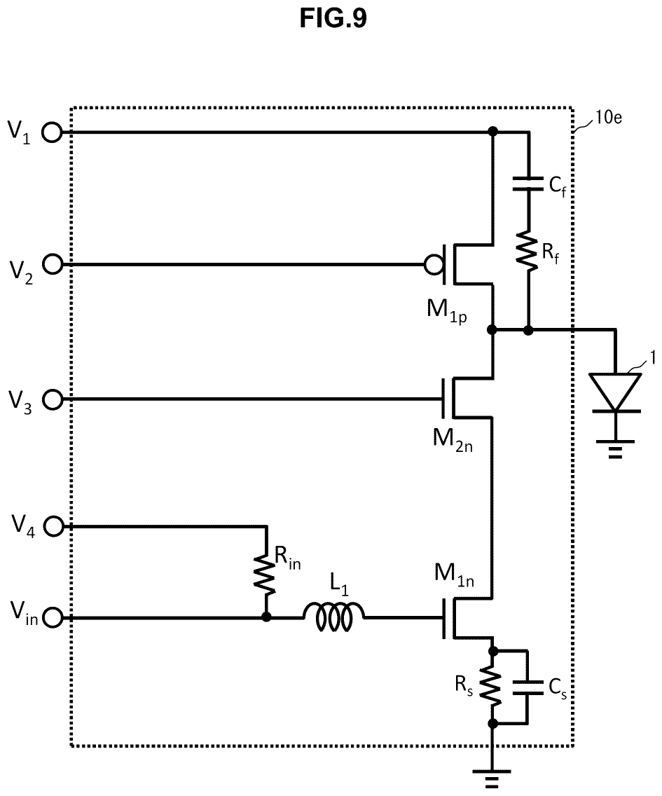

Next, the sixth embodiment of the present invention will be described. FIG. 9 is a circuit diagram showing the arrangement of a DML driver according to the sixth embodiment of the present invention. A DML driver 10e according to the sixth embodiment is constituted by connecting a capacitor Cₛ parallel to a resistor Rₛ in the DML driver 10d according to the fifth embodiment. In the sixth embodiment, compared to the fifth embodiment, the high-frequency band of a transmission front end constituted by the DML driver 10e and an LD 1 can be improved.

Although the resistor Rₛ and the capacitor Cₛ are applied to the first embodiment in FIG. 9, they may be applied to the second to fourth embodiments.

If the breakdown voltage of the NMOS transistor has no problem, it is possible to omit the NMOS transistors M₂ₙ and M₂ₙ-1 to M₂ₙ-y, and connect the drain of the NMOS transistor M₁ₙ and the anode of the LD 1 in the first to sixth embodiments. In this case, the bias voltages V₃ and V₃-1 to V₃-y become unnecessary.

In the third embodiment, if the breakdown voltage of the PMOS transistor has no problem, it is possible to omit the PMOS transistors M₂ₚ-1 to M₂ₚ-x, and arrange only the PMOS transistor M₁ₚ, similar to the first, second, and fourth to sixth embodiments. In this case, the bias voltages V₅-1 to V₅-x become unnecessary.

Although the MOS transistors are used as the transistors M₁ₚ, M₂ₚ-1 to M₂ₚ-x, M₁ₙ, and M₂ₙ-1 to M₂ₙ-y in the first to sixth embodiments, PNP bipolar transistors may be used as the transistors M₁ₚ and M₂ₚ-1 to M₂ₚ-x, and NPN bipolar transistors may be used as the transistors M₁ₙ and M₂ₙ-1 to M₂ₙ-y. When the bipolar transistor is used, the gate is replaced with the base, the drain is replaced with the collector, and the source is replaced with the emitter in the description of the first to sixth embodiments.

### INDUSTRIAL APPLICABILITY

The present invention can be applied to a technique of directly modulating the optical output of an LD.

### EXPLANATION OF THE REFERENCE NUMERALS AND SIGNS

1 . . . . LD, 10, 10a to 10e . . . . DML driver, M₁ₚ, M₂ₚ-1 to M₂ₚ-x . . . . PMOS transistor, M₁ₙ, M₂ₙ-1 to M₂ₙ-y . . . . NMOS transistor, L₁ . . . inductor, Rᵢₙ, R_{f}, Rₛ . . . resistor, C_{f}, Cₛ . . . capacitor

1. A DML driver comprising:
a first transistor having a gate or base connected to a first bias voltage, a source or emitter connected to a first power supply voltage, and a drain or collector connected to an anode of a laser diode;
a second transistor having a drain or collector connected to the anode of the laser diode, and a source or emitter connected to a second power supply voltage;
an inductor having one end to which a modulated signal is input, and the other end connected to a gate or base of the second transistor; and
a first resistor having one end connected to a second bias voltage, and the other end connected to the one end of the inductor.

2. The DML driver according to claim 1, further comprising a third transistor having a gate or base connected to a third bias voltage, and cascode-connected between the anode of the laser diode and the drain or collector of the second transistor.

3. A DML driver comprising:
a first transistor having a gate or base connected to a first bias voltage, a source or emitter connected to a first power supply voltage, and a drain or collector connected to an anode of a laser diode;
a second transistor having a gate or base connected to a second bias voltage, and a source or emitter connected to a second power supply voltage;
a third transistor cascode-connected between the anode of the laser diode and a drain or collector of the second transistor;
an inductor having one end to which a modulated signal is input, and the other end connected to a gate or base of the third transistor; and
a first resistor having one end connected to a third bias voltage, and the other end connected to the one end of the inductor.

4. The DML driver according to any one of claims 1 to 3, further comprising:
a first capacitor having one end connected to the first power supply voltage; and
a second resistor having one end connected to the other end of the first capacitor, and the other end connected to the drain or collector of the first transistor.

5. The DML driver according to any one of claims 1 to 4, further comprising a fourth transistor having a gate or base connected to a fourth bias voltage, and cascode-connected between the drain or collector of the first transistor and the anode of the laser diode.

6. The DML driver according to any one of claims 1 to 5, further comprising a third resistor inserted between the source or emitter of the second transistor and the second power supply voltage.

7. The DML driver according to claim 6, further comprising a second capacitor parallel-connected to the third resistor.
